(19) United States
(12) Patent Application Publication
(10) Pub. No.: US 2021/0399579 A1
(43) Pub. Date: Dec. 23, 2021

(54) Systems and Methods for Optimizing Cable Size and Flexibility Using Inductive Power Couplings

(71) Applicant: Hayward Industries, Inc., Berkeley Heights, NJ (US)

(72) Inventor: Troy Renken, Mooresville, NC (US)

(73) Assignee: Hayward Industries, Inc., Berkeley Heights, NJ (US)

(21) Appl. No.: 17/353,615

(22) Filed: Jun. 21, 2021

Related U.S. Application Data
(60) Provisional application No. 63/041,207, filed on Jun. 19, 2020.

(51) Int. Cl. H02J 50/10; H02G 3/22; G05F 1/12

(52) U.S. Cl. CPC H02J 50/10; G05F 1/12; H02G 3/22

(57) ABSTRACT

A system and method for optimizing cable size and flexibility for a pool or spa installation is provided. The system includes an inductive power coupling having first and second power couplings. The inductive power coupling transforms a first voltage level provided by the cable to a second voltage level suitable for usage by the pool or spa component and compensates for a voltage loss associated with the cable allowing the cable to have a size and flexibility suitable for installation in a pipe or conduit. The first power coupling is in electrical communication with a power supply via a cable and the second power coupling is in electrical communication with a pool or spa component. The first power coupling inductively transmits received power from the power supply via the cable to the second power coupling. The second power coupling inductively transmits the received power to the pool or spa component.

### RELATED APPLICATIONS

The present application claims priority to U.S. Provisional Patent Application Ser. No. 63/041,207 filed on Jun. 19, 2020, the entire disclosure of which is hereby expressly incorporated by reference.

### BACKGROUND

### Technical Field

The present disclosure relates generally to the pool and spa field. More specifically, the present disclosure relates to systems and methods for optimizing cable size and flexibility for an electrically-powered pool and/or spa device using inductive power couplings.

### Related Art

In the pool and spa field, electrically-powered devices such as underwater pool and/or spa lights, underwater pool and/or spa cleaners, and other devices are often powered using power cables that are run through buried pipes/conduits. The size and flexibility of such cables is determined by the current and voltage requirements of the electrically-powered devices, as well as the length of the required cable due to voltage drop issues associated with cable length (e.g., the longer the length of the cable, the greater the voltage drop). Additionally, existing cables utilized for underwater lighting for pools and/or spas are sized with voltage drop in mind, which results in wire gauges that are oversized for the current drawn. Often, these factors require the use of cables of larger thickness and current carrying capacity. This adds to the overall cost of installation, and reduces the flexibility of the cables (due to the larger thickness), thereby adversely affecting ease of installation. Indeed, when thicker cables are used, they are often difficult to pull (“fish”) through the buried pipes/conduits, thereby presenting a significant installation impediment and hassle for electricians and pool and/or spa installers.

Pool and spa devices can be powered using inductive power couplings positioned in, or near, pools and spas. Such inductive power couplings inductively transfer power from a first inductive component to a second inductive component that mates with the first inductive component, such that power is inductively transferred from the first inductive component to the second inductive component, and electrical power is then transferred from the second inductive component to the pool or spa device. The first inductive component is typically connected to a power supply using a power cable fed through a pipe or conduit. Advantageously, since the inductive components can also operate as step-up or step-down transformers, they can be employed to alter the voltage and/or current levels of the power cable in the pipe or conduit, so as to optimize the size and flexibility of the power cable and to address the foregoing, and other, issues associated with pulling such cables through pipes/conduits.

As such, it would be highly beneficial to develop systems and methods that can optimize cable size and flexibility, in view of a voltage requirement of an electrically-powered pool and/or spa device and a length of the required cable due to voltage drop issues with a high degree of accuracy, by utilizing inductive power couplings to facilitate power transfer between a power source and the electrically-powered pool and/or spa device. Accordingly, the systems and methods of the present disclosure addresses these and other needs.

### SUMMARY

The present disclosure relates to systems and methods for optimizing cable size and flexibility for an electrically-powered pool and/or spa device using inductive power couplings. The inductive power couplings inductively transfer power from a first inductive component to a second inductive component that mates with the first inductive component. The inductive components can operate as step-up or step-down transformers and can be employed to alter the voltage and/or current levels present in the power cable in the pipe or conduit, so as to optimize the size and flexibility of the power cable. The first inductive component can be mounted in or on a surface of a pool or spa and the second inductive component can be coupled directly to a pool and/or spa device or via a cable interconnecting the second inductive component and the pool and/or spa device. The first inductive component can be coupled to a power supply via a power cable fed through a pipe or conduit. The first inductive component includes an inductor circuit powered by the power supply such that mating of the first inductive component and the second inductive component inductively transfers power from the first inductive component to the second inductive component, and electrical power is then transferred from the second inductive component to the pool and/or spa device. Optionally, the inductive power couplings could be shaped as flat couplings, and/or they could include magnets located on the peripheries of the couplings for magnetically coupling the components.

In another embodiment, the present disclosure provides an inductive element, e.g., conduit or cable, which could be buried within a pool and/or spa floor or wall. This creates an electromagnetic field surrounding the inductive element, for wirelessly transmitting energy to an inductive circuit on-board a pool and/or spa device (e.g., to an underwater cleaner operated along the pool and/or spa floor or wall). The inductive components can operate as step-up or step-down transformers and can be employed to alter the voltage and/or current levels present in the power cable in the pipe or conduit, so as to optimize the size and flexibility of the power cable.

In another embodiment, the present disclosure provides inductive power couplings that can be installed in an existing plumbing fixture of a pool and/or a spa, for providing power to a pool and/or spa device. For example, the power coupling can be installed (retrofitted) into an existing suction outlet (and associated pipe) in a pool and/or a spa, to provide electrical power via such an outlet. A pool and/or spa device (e.g., a pool cleaner) could be connected to a complementary inductive power coupling which includes an inductor circuit. The complementary inductive power coupling of the underwater device can be inserted into the suction outlet and coupled with the inductive power coupling installed in the suction outlet. The inductive components can operate as step-up or step-down transformers and can be employed to alter the voltage and/or current levels present in the power cable in the pipe or conduit, so as to optimize the size and flexibility of the power cable.

### BRIEF DESCRIPTION OF THE DRAWINGS

The foregoing features of the present disclosure will be apparent from the following Detailed Description of the Invention, taken in connection with the accompanying drawings, in which:

FIG. 1 is a diagram illustrating an embodiment of the system of the present disclosure;

FIG. 2 is a flowchart illustrating processing steps carried out by the system of the present disclosure;

FIG. 3 is a diagram illustrating another embodiment of the system of the present disclosure;

FIGS. 4A-4C are perspective, top, and side views, respectively, illustrating an embodiment of an inductive coupling;

FIGS. 5A-5C are perspective, top, and cross-sectional views, respectively, illustrating a complementary inductive coupling;

FIGS. 6A-6C are perspective, top, and cross-sectional views, respectively, illustrating another embodiment of an inductive coupling;

FIGS. 7A-7C are perspective, top, and cross-sectional views, respectively, illustrating another embodiment of a complementary inductive coupling;

FIGS. 8A-8B are side views illustrating mating and operation of the couplings of FIGS. 4A-5C and of FIGS. 6A-7C, respectively;

FIG. 9 is a side view illustrating an underwater device being powered by an inductive power conduit or cable of the systems of the present disclosure;

FIG. 10 is a diagram illustrating an electrical schematic of a power supply unit of the system of FIG. 3;

FIG. 11 is a diagram illustrating an electrical schematic of an inductive circuit of the underwater device of FIG. 9 for obtaining power from the inductive power conduit or cable; and

FIG. 12 is a diagram of a partial sectional view of another embodiment of the system of the present disclosure.

### DETAILED DESCRIPTION

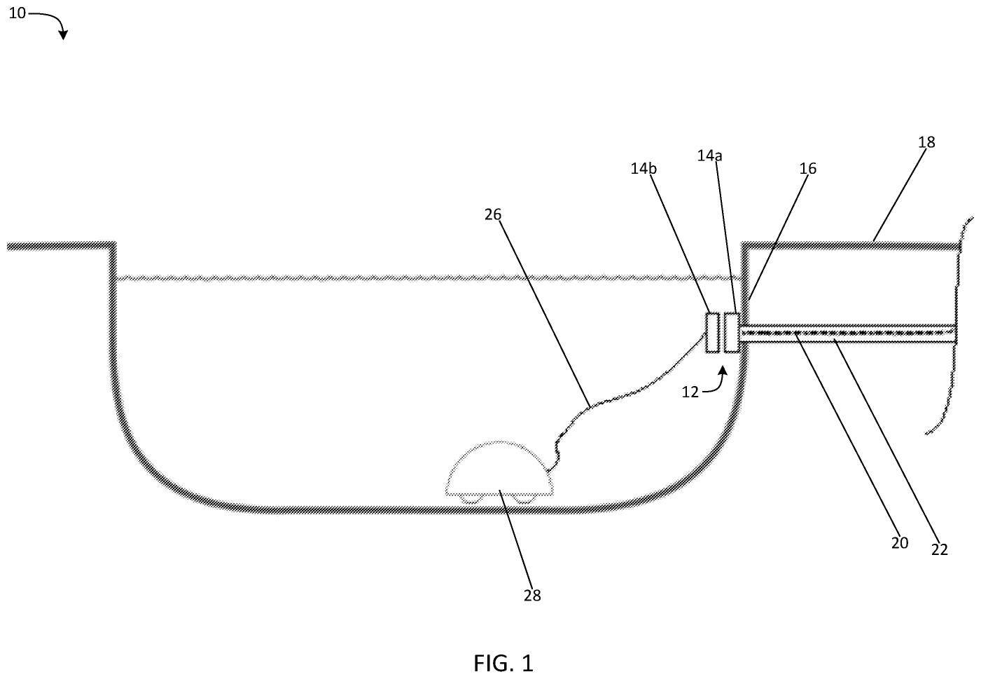

The present disclosure relates to systems and methods for optimizing cable size and flexibility for an electrically-powered pool and/or spa device using inductive power couplings, as described in detail below in connection with FIGS. 1-12.

FIG. 1 is a diagram illustrating an embodiment of the system 10 of the present disclosure. The system 10 includes an inductive power coupling 12 having a first power coupling 14a and a second power coupling 14b. The first power coupling 14a is supplied with electricity from a power source (not shown) connected to the first power coupling 14a by a power cable 20. The power cable 20 runs through a pipe or conduit 22. As used herein, the term “pipe” or “conduit” refers to pipes, conduits, fixtures, and/or other components in a spa and/or pool environment which are physically capable of receiving the power cable 20 of the system 10 of the present disclosure. The first power coupling 14a could be mounted to a surface 16 of a pool or spa 18, or at any other desired location (e.g., near the pool or spa 18, embedded within a surface of the pool or spa 18, or at any other desired location). The second power coupling 14b is coupled to the first power coupling 14a, and electrical power supplied by the cable 20 is inductively transmitted from the first power coupling 14a to the second power coupling 14b. The transmitted electrical power can then be utilized by any desired pool or spa device 28, such as a pool cleaner, an underwater light, or any other pool or spa device requiring electrical power. The pool or spa device 28 could be interconnected with the second inductive coupling 14b via a power cable 26, which transfers electrical power from the second inductive coupling 14b to the pool or spa device 28. Of course, the cable 26 is not required, and the second inductive coupling 14b could be directly attached to a pool or spa device (e.g., to an underwater light or other device).

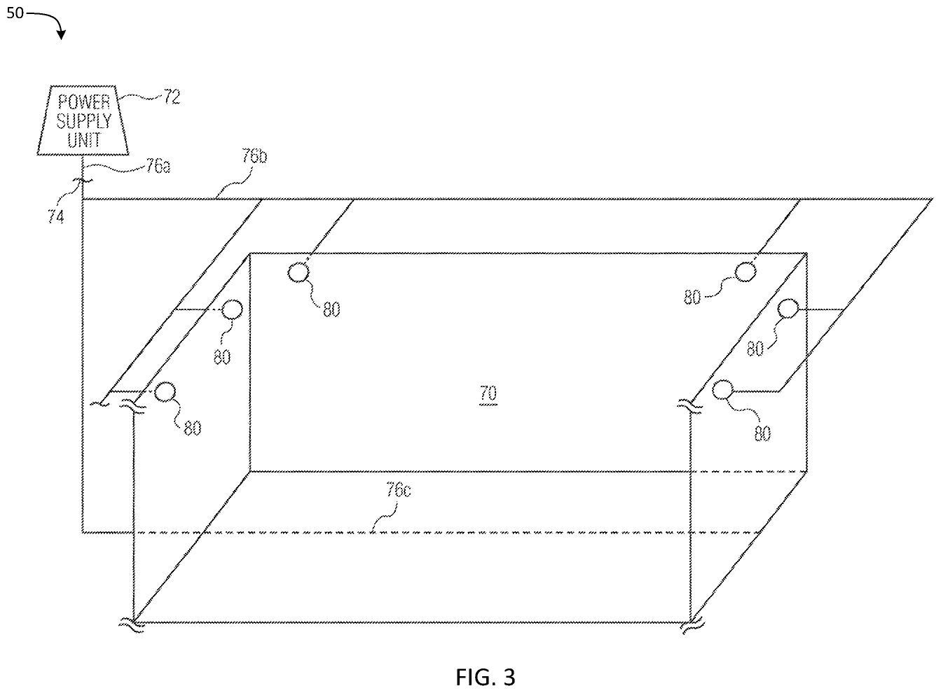

The inductive power coupling 12 of FIG. 1 could include one or more of the inductive power couplings described in detail below in connection with FIGS. 3-12. The power coupling 12 could function as a transformer, such that one of the couplings can receive electricity at one voltage level, and the second coupling can provide electricity to the pool or spa device 28 at a different voltage level, due to different wire “turns” in the couplings. Advantageously, this feature can be employed to optimize the size and flexibility of the cable 20, so as to reduce costs of the cable 20 and to provide a more flexible cable that can more easily be pulled through the conduit/pipe 22 during installation, while still providing adequate voltage levels required by the pool or spa device 28. Specifically, the couplings 14a and 14b could have the appropriate transformer ratio (or, “turns” ratio—e.g., the ratio of wire turns of the first coupling 14a to the wire turns of the second coupling 14b) so that the couplings provide the sufficient voltage to the pool or spa device 28 to operate, while allowing the cable 20 to be of a desired size, flexibility, and cost, and compensating for voltage losses attributable to the cable 20.

It is further noted that the transformer function of the power coupling 12 could also be supplied using microprocessor-controlled pulse-width modulation (PWM) circuitry in the couplings 14a and 14b. For example, the first power coupling 14a could be programmed with the minimal acceptable voltage, current, or power level needed by the pool or spa device 28, and the microprocessor of the coupling 14a could provide a PWM signal in response to the minimal acceptable voltage current, or power level and which compensates for voltage losses of the cable 20. The PWM signal is then received by the power coupling 14b, and corresponding circuitry in the coupling 14b converts the PWM signal to an electrical power signal suitable for usage by the pool or spa device 28 and having the voltage, current, or power level required by the pool or spa device 28. In such circumstances, the transmission of power via PWM also allows for selection of the cable 20 so that it has a desired size and flexibility, while still providing sufficient electrical power to the pool or spa device 28. In this arrangement, the transformer function is not provided by the ratio of wire turns in the couplings 14a and 14b, but rather, by high-frequency, microprocessor-controlled PWM signaling between the couplings 14a and 14b.

It is additionally noted that the transformer function provided by the coupling 12 allows for usage of a power supply that has a single-insulated transformer, instead of the double-insulated transformer normally required in power supplies utilized in pool and spa applications. This allows for cost reduction in the design of the power supply, while still permitting compliance with relevant electrical codes, testing, and/or regulations. Additionally, the coupling 12 allows the wires of the cable 20 to be sized per the ampacity requirement (instead of voltage drop), which allows for a lower cost, smaller sized cable.

It is further noted that cable flexibility is governed by the “bend radius” of the cable 20, and is related to the size (gauge) of the cable. As such, if it is desired that the cable 20 have a desired bend radius suitable for particular installation, the cable 20 can be selected to have a size (gauge) sufficient to provide such bend radius, and accordingly, the desired flexibility for that installation. The inductive power coupling 12 can compensate for voltage losses associated with such cable gauge, while still providing the desired electrical power to the pool or spa device 28. Because of this feature, the power coupling 12 allows the pool/spa installer to utilize an optimal cable from the perspective of ease of installation and cost reduction, while still supplying adequate power. Still further, since the power coupling 12 allows smaller gauge cables to be used, it also allows the size (diameter) of pipes/conduits through which the cables are installed to be reduced, thereby representing additional cost savings.

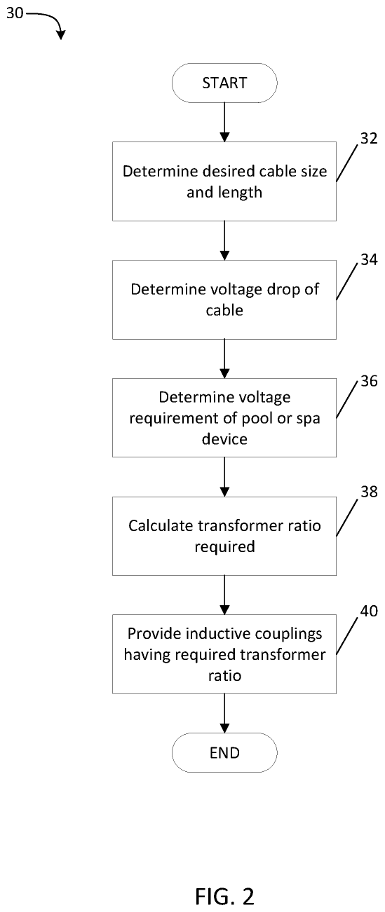

The selection of the appropriate transformer ratio of the coupling 12 is based on: (1) the desired length of the cable 20, (2) the desired size of the cable 20 (e.g., the gauge of the cable), (3) the voltage drop of the cable 20, and (4) the voltage requirement of the pool or spa device 28. For example, as shown in the flowchart 30 of FIG. 2, in step 32, the desired cable size and length is determined (e.g., the desired gauge and length of the cable 20 is determined). The cable size determines the flexibility of the cable and the ease with which the cable can be installed in (e.g., pulled through) the conduit/pipe 22. In step 34, the voltage drop of the cable 20 is calculated. This could be accomplished using known voltage drop tables which specify the voltage drops of various cable sizes for given cable lengths. In step 36, the voltage requirement of the pool or spa device 28 is determined. In step 38, the transformer ratio is calculated based on the cable size, cable length, voltage drop, and voltage requirement. Finally, in step 40, the inductive couplings 14a and 14b are provided having the required transformer ratio. In so doing, the coupling 12 transforms the voltage supplied to the pool or spa device 28 to an acceptable voltage suitable for operation of the pool or spa device 28, while the cable 20 has the desired size and flexibility and any voltage loses of the cable 20 are compensated for by the coupling 12.

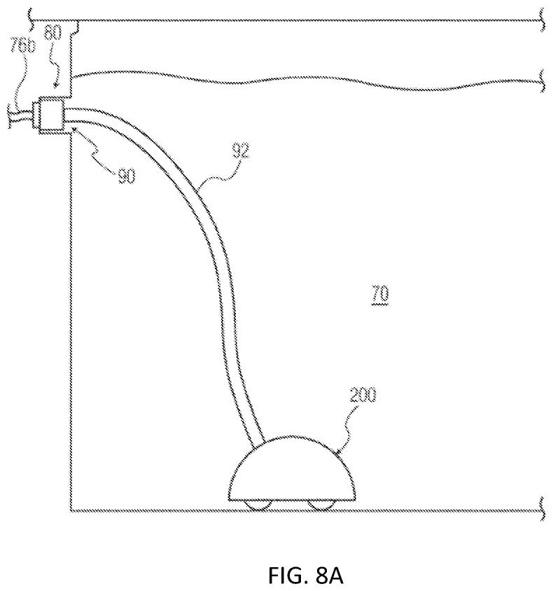

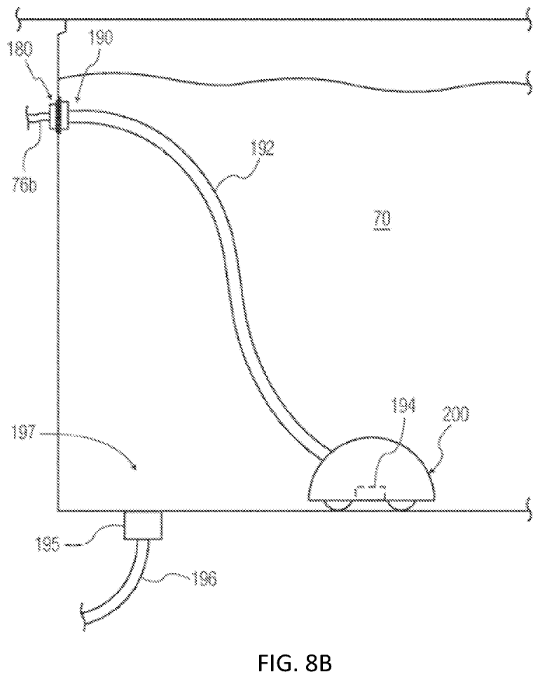

FIG. 3 is a diagram illustrating another embodiment of the system of the present disclosure. As shown in FIG. 3, the system 50 can include a power supply unit 72 connected to inductive power coupling couplings 80 installed in the walls of the pool 70. Of course, the couplings 80 could also be installed in the floor of the pool 70. The power supply unit 72 provides electrical power to the inductive power coupling couplings 80 via conduits 76a, 76b. The power supply conduit 76a connects to the power supply unit 72 and extends below ground 74. Below ground, the conduit 76b is positioned and connected to the inductive power coupling couplings 80, and, optionally, to a buried inductive power conduit and/or cable 76c. Inductive power coupling couplings 80 and inductive power conduit/cable 76c function allow for inductive transmission of electrical power from the power supply 72 to an underwater device, such as an underwater pool/spa cleaner (as shown in FIGS. 8A-8B). The couplings 80 could have the appropriate transformer ratio so that the couplings provide the sufficient voltage to a pool or spa device to operate, while allowing cables run through the conduits 76a, 76b (which supply electrical power to the couplings 80) to be of a desired size, flexibility, and cost, and compensating for voltage losses attributable to the cables.

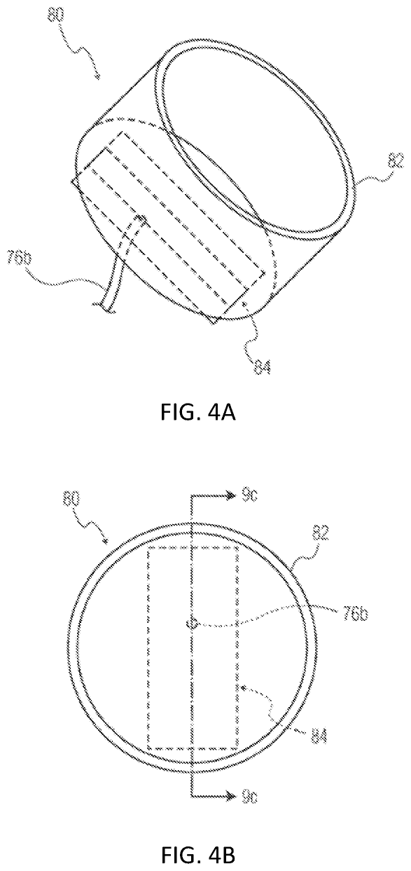

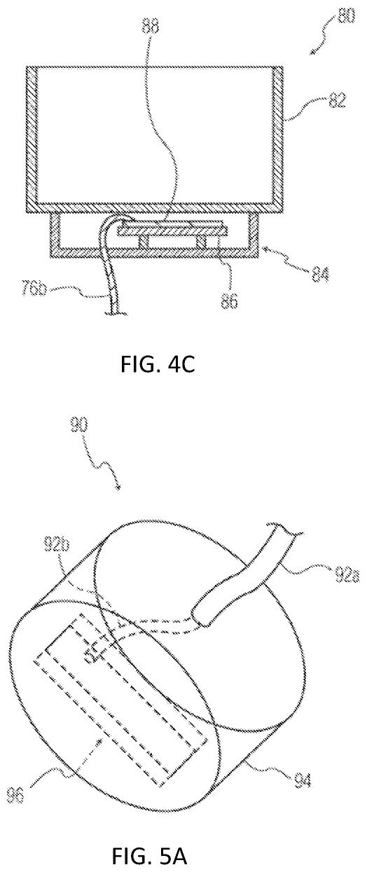

FIGS. 4A-4C are perspective, top, and cross-sectional views, respectively, illustrating an embodiment of the inductive power coupling 80 of the system 50 of FIG. 3. The inductive power coupling 80 includes a housing 82 which is generally embedded in a pool or spa wall. The housing 82 defines a recess which receives a corresponding inductive power coupling from a pool or spa device, which will be described in greater detail below. The housing 82 could be made of a plastic material such as polyvinyl chloride (PVC) or any other sturdy waterproof material that does not interfere with electrical field transmission, and which is an electrical insulator. Of course, other materials could be utilized. Attached to the external surface of the rear wall of the housing 82 is circuitry housing 84. The circuitry housing 84 houses an inductor circuit 88 which allows for the inductive transmission of electrical power. The housing 82 defines a cavity allowing for the insertion of a complementary inductive coupling. Attached to the rear of the housing wall 82 is the circuitry housing 84. Enclosed within the circuitry housing 84 is a circuit board 86 which includes the inductor circuit 88. Providing power to the inductor circuit 88 a cable 76b. As noted above, the couplings 80 could have the appropriate transformer ratio so that the couplings provide the sufficient voltage to a pool or spa device to operate, while allowing the cable 76b to be of a desired size, flexibility, and cost, and compensating for voltage losses attributable to the cable.

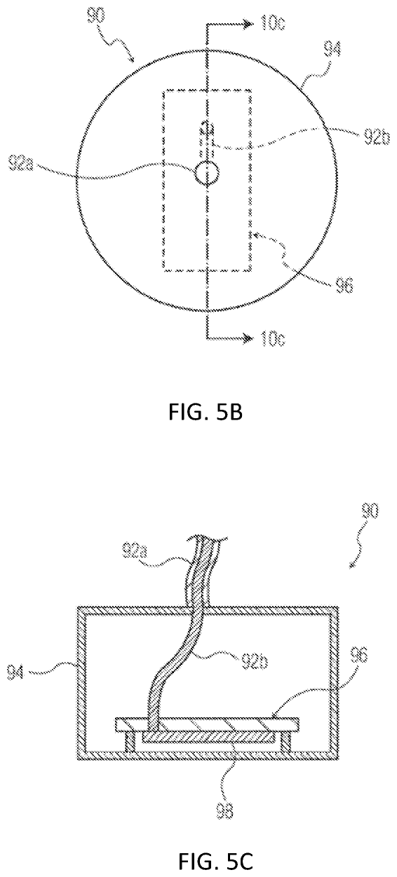

FIGS. 5A-5C are perspective, top, and cross-sectional views, respectively, illustrating a complementary inductive coupling 90 of the system 50 of FIG. 3. The coupling 90 includes a housing 94 which is tethered to a pool or spa device such as a cleaner. The housing 94 could be made of a plastic material such as polyvinyl chloride (PVC) or any other sturdy, waterproof material that does not interfere with inductive power transmission. Attached to the inner surface of the front wall of the housing 94 is the circuitry housing 96. The circuitry housing 96 houses the inductor circuit 98 and allows for the power conduit 92b to supply the inductor circuit 98 with electrical power. Power cable 92b runs from the pool or spa apparatus, for example pool cleaner, to the inductor circuit 98. The cable 92b could be encased in a waterproof sheath 92a.

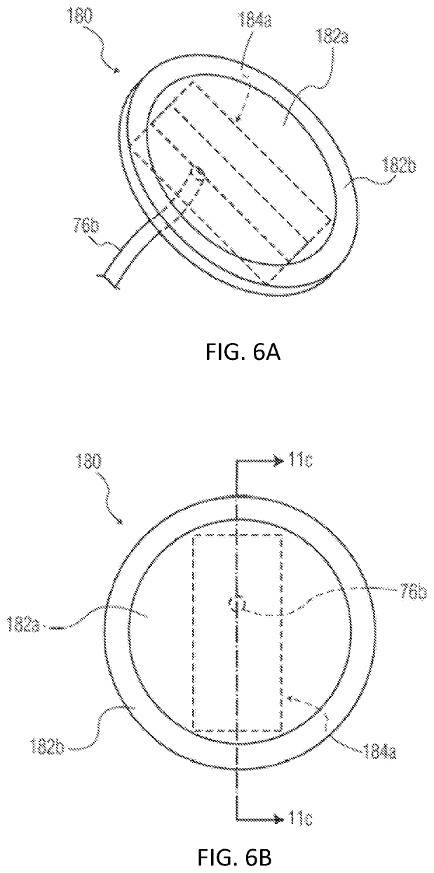

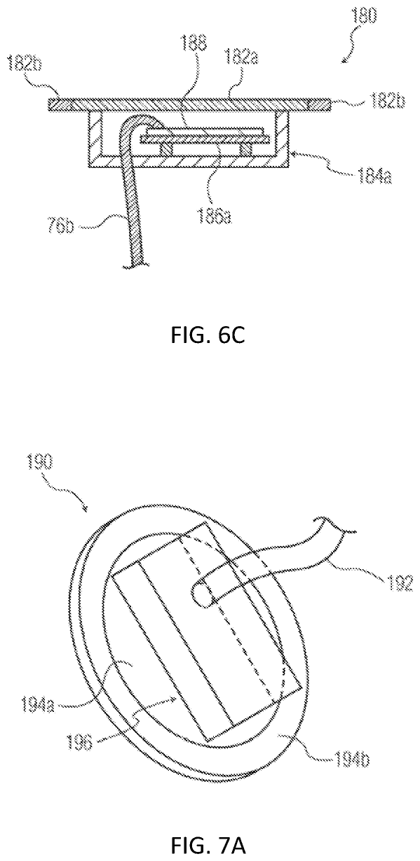

FIGS. 6A-6C are perspective, top, and cross-sectional views, respectively, illustrating another embodiment of an inductive coupling 180 of the system 50, wherein a flat coupling is provided. The coupling 180 comprises a flat plate 182a formed of a plastic material such as polyvinyl chloride (PVC) or any other sturdy waterproof material that does not interfere with inductive power transmission. Surrounding the periphery of the plate 182a is a magnetic ring 182b. Optionally, the ring 182b may be formed of a ferromagnetic metal. When installed, the plate 182a and magnetic ring 182b are generally bonded to a pool wall or positioned within a pool wall. Attached to the rear surface of the plate 182a is the circuitry housing 184a. The circuitry housing 184a houses the inductor circuit 188 and allows for the power conduit 76b to supply the inductor circuit 188 with electrical power. Enclosed within the circuitry housing 184a is a mounting board 186a which is attached to the inner surface of the circuitry housing 184a rear wall.

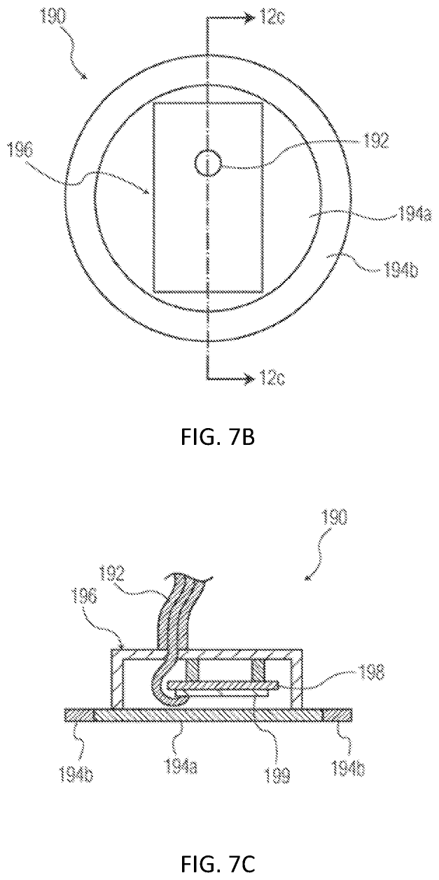

FIGS. 7A-7C are perspective, top, and cross-sectional views, respectively, of another embodiment of a complementary inductive coupling 190 of the system 50 of FIG. 3. The complementary coupling 190 is tethered to underwater pool/spa equipment, and mates with the coupling 180 of FIGS. 6A-6C. The coupling 190a includes a flat plate 194a formed of a plastic material such as polyvinyl chloride (PVC) or any other sturdy waterproof material that does not interfere with inductive power transmission. Surrounding the periphery of the plate 194a is a ferromagnetic metal ring 194b. Optionally, the ring 194b may be formed of a magnet. Attached to the rear surface of the plate 194a is the circuitry housing 196, which houses the inductor circuit 199 which is connected to a power cable 192 connected to underwater pool/spa equipment. The circuit 199 could be mounted to a mounting board 198, as shown.

FIGS. 8A-8B are side views illustrating mating and operation of the couplings 80, 90 of FIGS. 4A-5C and 180, 190 of FIGS. 6A-7C, respectively. As shown, the couplings allow an underwater pool/spa device, such as an underwater electric pool/spa cleaner 200, to be removably connected to a power source. Advantageously, the couplings 80, 90 and 180, 190 allow for quick connection and disconnection, and due to their insulated nature, the risk of electric shock is obviated. Moreover, since the couplings have smooth surfaces, they are easy to clean.

Referring to FIG. 8B, it is noted that a docking area or “station” 197 could be provided in a pool or spa, to which area or station the pool/spa cleaner 200 automatically travels and docks to periodically recharge the on-board battery of the pool/spa cleaner. In such circumstances, the cable 192 need not be provided. Instead, an inductive coupling 195 is embedded in a surface of the pool or spa (e.g., in the floor of the pool 70 as shown in FIG. 8B), and a corresponding inductive circuit 194 is provided on-board the cleaner 200. A power cable 196 provides electrical energy to the coupling 195. When the cleaner 200 detects a low battery condition (e.g., by way of built-in monitoring circuitry and/or logic), the cleaner 200 automatically navigates to the docking area 197, such that the inductive circuit 194 is positioned above the coupling 195 and electrical power is inductively transmitted from the coupling 195 to the circuit 194, and the battery is charged by such power. It is also noted that a recess could be provided in the wall of the pool or spa, the inductive coupling 195 could be positioned within the recess, and the cleaner 200 could navigate to and park itself in the recess to perform periodic charging operations.

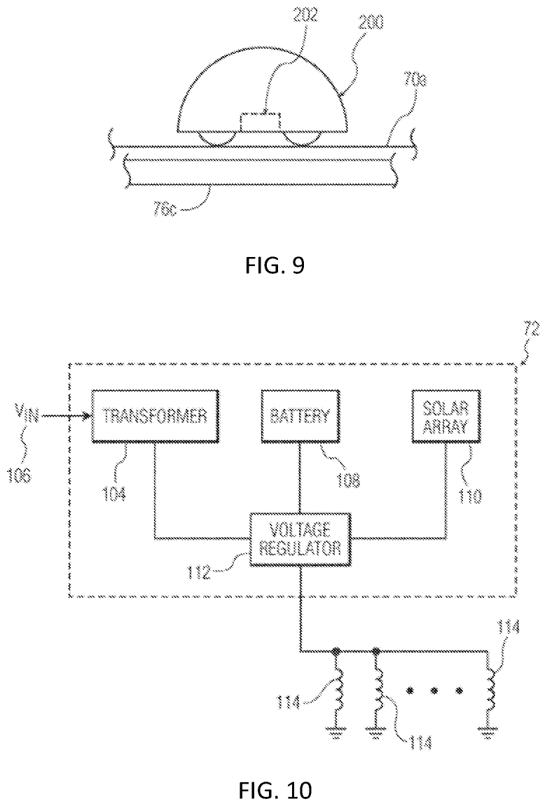

FIG. 9 is a side view illustrating a pool cleaner 200 including an on-board inductive circuit 202 which allows for inductive transmission of power from the buried inductive element 76c, e.g., conduit/cable, to the cleaner 200. As the cleaner 200 travels along the floor 70a of the pool, the inductive element 76c transmits electrical power to the inductive circuit 202, to power the cleaner 200. The buried inductive element 76c and a corresponding inductive element of the cleaner 200 could have the appropriate transformer ratio so that sufficient voltage is provided to operate the cleaner 200, while allowing a cable supplying power to the buried element 76c to be of a desired size, flexibility, and cost, and compensating for voltage losses attributable to the cable.

FIG. 10 is a diagram illustrating an electrical schematic of the power supply unit 72 of the system 50 of FIG. 3. The power supply 72 could step down an input voltage 106 via a transformer 104 to provide power to inductors 114 (which could be positioned within the couplings 80, 90). Optionally, the transformer 104 could be a step-down transformer (e.g., 120 VAC to 12 VAC), and/or it could be an isolation transformer. Further, the power supply 72 could include a voltage regulator 112 for regulating voltage supplied to the inductors 114. Still further, the power supply 72 could be powered by an internal battery 108 (e.g., rechargeable nickel cadmium, nickel metal hydride, lithium ion, lithium polymer battery, etc.), and/or via a solar array 110, either (or both) of which could be connected to the inductors 114 via a voltage regulator 112. The solar array 110 could charge the battery 108 in periods of sunlight.

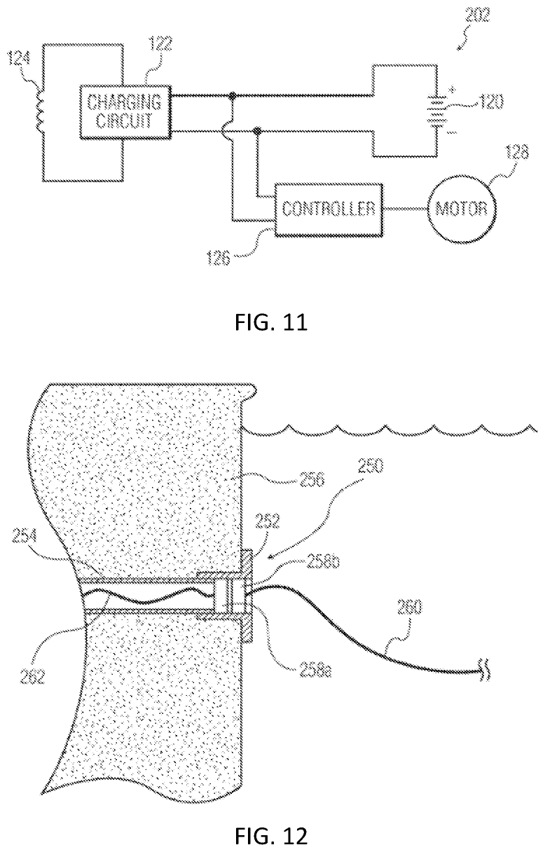

FIG. 11 is a diagram illustrating an electrical schematic of the inductive circuit 202 of the pool cleaner 200 of FIG. 9 for obtaining power from the buried inductive power conduit/cable 76c of the system of FIG. 3. An inductor 124 wirelessly receives power from the conduit/cable 76c, which could supply power to an optional charging circuit 122 for charging an on-board battery 120 of the cleaner 200. The inductor 124 could also power a controller 126 and a motor 128 of the cleaner 200. When the cleaner is not being used, it could be “parked” in proximity to the buried cable/conduit 76c, so that the inductor 124 wirelessly receives power from the cable/conduit 76c and charges the battery 120. When the battery 120 is charged, the cleaner 200 could operate at any location within the pool. Also, the controller 126 could include embedded logic which automatically detects when the battery 120 is low, and automatically navigates the cleaner 200 toward the conduit/cable 76c so that power is inductively obtained from the conduit/cable 76c to charge the battery 120.

FIG. 12 is a diagram of a partial sectional view of another embodiment of the system 250 of the present disclosure, wherein inductive power couplings are provided in an existing plumbing fixture, e.g., suction port 252 and pipe 254, in a pool or spa 256. This arrangement is particularly advantageous as a “retrofit” solution for existing pools or spas. Conventional operation of the suction port 252 and pipe 254 can be disabled, and the port 252 and pipe 254 are instead used to deliver electrical power. As shown in FIG. 12, a first inductive coupling 258a is mounted within the suction port 252, and an electrical cable 262 is “pulled” through the pipe 254 and subsequently connected (e.g., at an equipment pad) to a power supply circuit (e.g., that steps power down from 120 volts A.C. to 12 volts A.C.). The coupling 258a could be retained in place by way of a friction fit, a snap fit, gluing, etc., or in any other suitable fashion. A corresponding inductive coupling 258b is sized and shaped to be removably received by the port 252, and electrical power is inductively transmitted from the coupling 258a to the coupling 258b when the coupling 258b is positioned within the port 252. A cable 260 connects the coupling 258b to pool/spa equipment (e.g., to a pool cleaner), and transfers electrical power to the same. It is noted that the arrangement shown in FIG. 12 could also be applied to other types of outlets existing in a pool or spa, and operation of such outlets (including the suction port 252 and pipe 254) may be active and need not be disabled. In other words, the inductive couplings could be positioned within such outlets but need not form a seal, so that water can still flow around the couplings, thereby permitting normal operation of such outlets. The couplings 258a, 258b could have the appropriate transformer ratio so that sufficient voltage is provided to operate a pool or spa device, while allowing the cable 262 to be of a desired size, flexibility, and cost, and compensating for voltage losses attributable to the cable.

It is noted that the inductive power couplings discussed herein could be utilized to provide power to pool/spa equipment not only for powering operation of these devices, but also to charge any on-board batteries that may be provided in such devices. Further and as described above, the inductive power couplings could be configured so as to change voltage levels. For example, an inductive coupling embedded in a wall of a pool or a spa could receive electricity at a first voltage (e.g., 120 volts A.C.), and a corresponding coupling could deliver power to a device in a pool or a spa at a different voltage level (e.g., 12 volts A.C.). This could be achieved by different numbers of wire “turns” provided in the couplings, such that the two couplings, when positioned near each other, function as an electrical transformer. Further, it is noted that the systems and methods described herein could be employed for powering a wide array of pool/spa devices, including, but not limited to, cleaners, underwater lights (luminaires), pumps (e.g., water feature pumps), or any other component in a pool or spa environment capable of being powered by electricity.

Having thus described the present disclosure in detail, it is to be understood that the foregoing description is not intended to limit the spirit or scope thereof. What is desired to be protected by Letters Patent is set forth in the following claims.

What is claimed is:

1. A system for optimizing cable size and flexibility for a pool or spa installation, comprising:
an inductive power coupling having a first power coupling and a second power coupling inductively coupled to the first power coupling, the first power coupling in electrical communication with a power supply and the second power coupling in electrical communication with a pool or spa component,
the first power coupling accepting power from the power supply via a first cable interconnecting the power supply and the first power coupling and inductively transmitting the power to the second inductive power coupling, the second power coupling inductively receiving the power from the first power coupling and transmitting the received power to the pool or spa component,
the inductive power coupling operating as a transformer for transforming a first voltage level provided by the first cable to a second voltage level suitable for usage by the pool or spa component, and
the inductive power coupling compensating for a voltage loss associated with the first cable and allowing the first cable to have a size and a flexibility suitable for installation in a pipe or conduit.

2. The system of claim 1, wherein the first power coupling is mounted in or on at least one of an interior surface of the pool or spa or an exterior surface of the pool or spa.

3. The system of claim 1, wherein the power supply is one or more of an A/C power supply, a battery, or a solar array.

4. The system of claim 1, wherein the second power coupling is in electrical communication with the pool or spa component via direct attachment to the pool or spa component or a second cable.

5. The system of claim 1, wherein the pool or spa component is one or more of a cleaning device or a luminaire.

6. The system of claim 5, wherein the cleaning device includes a rechargeable battery rechargeable by the power supply.

7. The system of claim 1, wherein the inductive power coupling operates as a step-up transformer or a step-down transformer.

8. The system of claim 1, wherein the inductive power coupling transforms the first voltage level provided by the first cable to the second voltage level suitable for usage by the pool or spa component based on a transformer ratio of the inductive coupling.

9. The system of claim 8, wherein the transformer ratio is defined by a ratio of wire turns of the first power coupling to wire turns of the second power coupling.

10. The system of claim 1, wherein the inductive power coupling transforms the first voltage level provided by the first cable to the second voltage level suitable for usage by the pool or spa component using pulse width modulation.

11. The system of claim 1, wherein
the first power coupling generates, in response to a minimum voltage, current or power level required by the pool or spa component, a pulse width modulation signal which compensates for voltage loss of the first cable and transmits the generated pulse width modulation signal to the second power coupling, and
the second power coupling receives the pulse width modulation signal and converts the received pulse width modulation signal to an electrical signal indicative of a voltage, current or power level required by the pool or spa component.

12. The system of claim 1, wherein the first power coupling includes a housing defining a cavity for receiving the second power coupling.

13. The system of claim 12, wherein the second power coupling is configured to be inserted into the housing of the first power coupling.

14. The system of claim 1, wherein the first and second power couplings are flat plates, each including means for releasably securing the inductive couplings to each other.

15. The system of claim 14, wherein the means for releasably securing the inductive couplings to each other are magnetic.

16. A method for optimizing cable size and flexibility for a pool or spa installation, comprising the steps of:
determining a desired cable size of a cable connected to a power supply;
determining a desired length of the cable;
determining a voltage drop of the cable;
determining a voltage requirement of a pool or spa device to be powered;
calculating a transformer ratio based on the desired cable size, the desired length of the cable, the voltage drop of the cable, and the voltage requirement of the pool or spa device; and
inductively coupling the pool or spa device with the cable using an inductive coupling having the transformer ratio, the inductive coupling compensating for the voltage drop of the cable while providing electrical power sufficient to power the pool or spa device.

17. The method of claim 16, wherein the power supply is one or more of an A/C power supply, a battery, or a solar array.

18. The method of claim 16, wherein the pool or spa device is one or more of a cleaning device or a luminaire.

19. The method of claim 16, wherein the cable is installed in a pipe or conduit.

20. The method of claim 16, wherein the transformer ratio is indicative of a ratio of wire turns of a first component of the inductive coupling to wire turns of a second component of the inductive coupling.
